(19) United States
(12) Patent Application Publication
(10) Pub. No.: US 2026/0371947 A1
(43) Pub. Date: Nov. 19, 2026

(54) Angled Material Deposition on Patterning Lines

(71) Applicant: Applied Materials, Inc., Santa Clara, CA (US)

(72) Inventors: Charith Nanayakkara, Gloucester, MA (US); John Hautala, Beverly, MA (US); Chih-An Hsu, Milpitas, CA (US); Huixiong Dai, San Jose, CA (US)

(73) Assignee: Applied Materials, Inc., Santa Clara, CA (US)

(21) Appl. No.: 19/207,912

(22) Filed: May 14, 2025

(51) Int. Cl. H10P 14/24; H10P 14/20; H10P 50/00; H10P 76/20

(52) U.S. Cl. CPC H10P 14/24; H10P 14/27; H10P 50/692; H10P 50/73; H10P 76/20; H10P 14/3406; H10P 14/3408; H10P 14/3411

(57) ABSTRACT

Disclosed are approaches for forming semiconductor device layers. One method may include providing a plurality of patterning lines over a stack of layers of a semiconductor structure, forming a film layer atop the plurality of patterning features by directing a material at a non-zero angle relative to a normal extending perpendicular from a plane defined by an upper surface of the semiconductor structure, wherein the film layer is formed along the upper surface of the plurality of patterning features without being formed along a sidewall of the plurality of patterning lines. An etch process may then be performed to recess the plurality of spaces into the stack of layers.

### FIELD

Embodiments of the present disclosure relate generally to substrate processing equipment and techniques, and more particularly, to approaches for forming a material layer atop patterning lines using directional deposition.

### BACKGROUND

In the integrated circuit (IC) industry, functional density (i.e., the number of interconnected devices per wafer area) has generally increased while geometry size (i.e., the smallest component that can be created using a fabrication process) has decreased. This scaling down process generally provides benefits by increasing production efficiency and lowering associated costs. However, such scaling down introduces challenges in maintaining process variations at acceptable levels within a wafer, wafer to wafer, and lot to lot.

As process geometries continue to decrease, for example, with extreme ultraviolet (EUV) lithography and high numerical aperture (NA) EUV lithography, photoresist line/space patterns are created with heights less than 15nm and critical dimensions (CDs) of less than 15nm. These shorter and more densely packed patterned lines result in multiple types of defects, such as line breaking, line collapsing, and over-etching during a subsequent etch step, which decreases yields of the IC manufacturing process.

Therefore, there is an ongoing need to improve yields by increasing etch margin, improving pattern shaping, and better controlling critical dimension (CD).

### SUMMARY OF THE DISCLOSURE

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In some approaches, a method may include providing a plurality of patterning lines over a stack of layers of a semiconductor structure, and forming a film layer atop the plurality of patterning features by directing a material at a non-zero angle relative to a normal extending perpendicular from a plane defined by an upper surface of the semiconductor structure, wherein the film layer is formed along the upper surface of the plurality of patterning features without being formed along a sidewall of the plurality of patterning lines.

In some approaches, a method of forming a material layer atop a plurality of patterning lines may include providing the plurality of patterning lines and a plurality of spaces over a stack of layers of a semiconductor structure, and forming the material layer atop the plurality of patterning lines by directing a material at a non-zero angle relative to a normal extending perpendicular from a plane defined by an upper surface of the plurality of pattering lines. The material layer may be formed along the upper surface of the plurality of patterning lines without being formed along a sidewall of the plurality of patterning lines.

In some approaches, a pattern transfer process may include providing a plurality of patterning lines and a plurality of spaces over a stack of layers of a semiconductor structure, and forming a material layer atop the plurality of patterning lines by directing a material at a non-zero angle relative to a normal extending perpendicular from a plane defined by an upper surface of the plurality of pattering lines. The material layer may be formed along the upper surface of the plurality of patterning lines without being formed along a sidewall of the plurality of patterning lines.

### BRIEF DESCRIPTION OF THE DRAWINGS

By way of example, embodiments of the disclosure will now be described, with reference to the accompanying drawings, in which:

FIG. 1A depicts a top view of an exemplary semiconductor structure including a plurality of patterning lines, in accordance with embodiments of the present disclosure;

FIG. 1B depicts a side cross-sectional view along cutline A-A in FIG. 1A, in accordance with embodiments of the present disclosure;

FIG. 2A depicts a top view of the exemplary semiconductor structure during a material deposition process, in accordance with embodiments of the present disclosure;

FIG. 2B depicts a side cross-sectional view along cutline A-A in FIG. 2A, in accordance with embodiments of the present disclosure;

FIG. 3A depicts a top view of the exemplary semiconductor structure following the material deposition process, in accordance with embodiments of the present disclosure;

FIG. 3B depicts a side cross-sectional view along cutline A-A in FIG. 3A, in accordance with embodiments of the present disclosure.

FIG. 4 is a side cross-sectional view of the exemplary semiconductor structure during an etch process, in accordance with embodiments of the present disclosure;

FIG. 5 is a schematic diagram of a system for forming the device structure, in accordance with embodiments of the present disclosure;

FIG. 6 is a schematic diagram of another system for forming the device structure, in accordance with embodiments of the present disclosure;

FIG. 7A depicts a system according to embodiments of the disclosure;

FIG. 7B depicts a plan view of an apparatus of the system of FIG. 7A according to embodiments of the disclosure; and

FIG. 8 shows a semiconductor processing apparatus according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### DETAILED DESCRIPTION

Methods, devices, structures, and systems in accordance with the present disclosure will now be described more fully hereinafter with reference to the accompanying drawings, where embodiments are shown. The methods, devices, structures, and systems may be embodied in many different forms and are not to be construed as being limited to the embodiments set forth herein. Instead, these embodiments are provided so the disclosure will be thorough and complete, and will fully convey the scope of the methods, devices, structures, and systems to those skilled in the art.

Embodiments described herein generally relate to techniques for forming semiconductor structures using a plurality of patterning features/lines with increased etch margin. In some embodiments, a material (e.g., film) is directionally deposited over the plurality of patterning lines, which may be patterned from a photoresist or hardmask. Advantageously, the angled deposition minimizes or prevents material from being deposited within the spaces defined by the plurality of patterning lines, i.e. along the bottoms of the trenches between the patterned lines. In some embodiments, a plasma or ion beam process may be used to build up the film atop an upper surface of the patterning lines, while maintaining the CD of the patterning lines, and without depositing material atop the surfaces between the pattering lines. In some embodiments, ion bias can be used to have ions and radicals in the beam.

In one non-limiting example, a carbon (C) or silicon (Si)-based film may be deposited at a non-zero angle (e.g., between 10° – 80°) relative to a normal extending perpendicular from the upper surface of the photoresist or hardmask, which has been patterned into a plurality of substantially perpendicular lines. In some embodiments, an angled deposition may be performed followed by a 180-degree rotation of the substrate and subsequent angled deposition, which translates to a minimum of two rotations for a single beam to achieve a symmetric deposition onto the line/space patterned structure. In other embodiments using a dual beam process, no rotation may be required. Deposition of the film layer atop the patterning lines may be performed while the substrate is maintained at less than 120°C, but could be higher for other films.

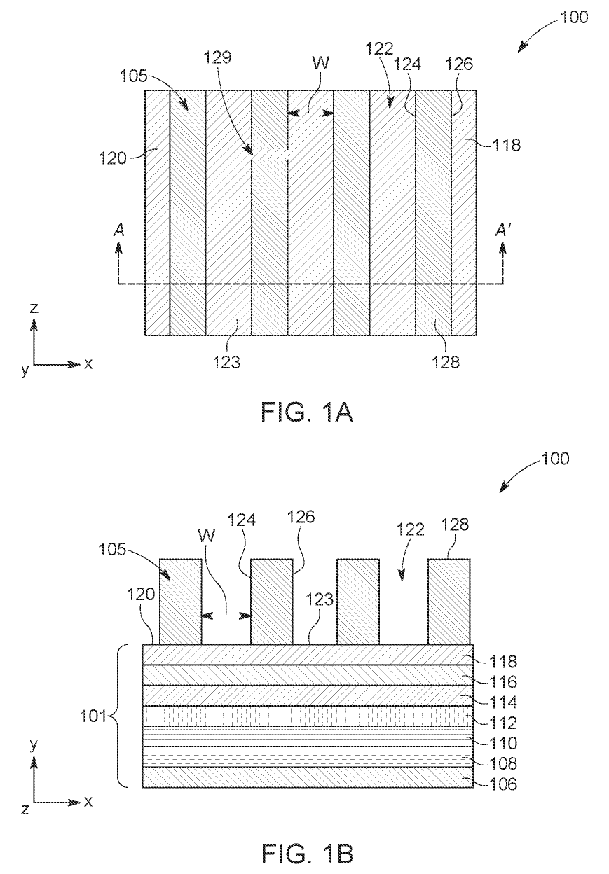

FIGS. 1A – 1B demonstrate a semiconductor device or structure 100, according to embodiments of the disclosure. Although non-limiting, the structure 100 may include a stack of layers 101, and a plurality of patterning features 105 formed over the stack of layers 101. Although not limited to any specific type of layer(s) and/or layer arrangement, the stack of layers 101 may include a base layer 106, a first oxide layer 108 formed over the base layer 106, a first hardmask 110 formed over the first oxide layer 108, a second oxide layer 112 formed over the first hardmask 110, a carbon layer 114 formed over the second oxide layer 112, a second hardmask 116 (e.g., silicon, silicon nitride, other hardmask materials) formed over the carbon layer 114, and an underlayer 118 formed over the second hardmask 116.

As shown, the patterning features 105 are formed over an upper surface 120 of the stack of layers 101, wherein the patterning features 105 may be lines formed from a photoresist or hardmask material, or from an underlayer material. In some embodiments, the photoresist may be a metal oxide resist or a chemically amplified resist formed directly atop the upper surface 120 of the stack of layers 101 and then patterned (e.g., developed, etched, or otherwise removed) to form a plurality of openings or spaces 122. In other embodiments, other materials, such as an AR coating or an underlayer may be between the patterning features 105 and the upper surface 120. In some embodiments, the spaces 122 are trenches formed selective to the upper surface 120. Each of the patterning features 105 may be defined by a first sidewall 124, a second sidewall 126, and an upper surface 128 extending between the first and second sidewalls 124, 126. Each of the spaces 122 may be defined by the first sidewall 124, the second sidewall 126, and a bottom surface 123 between the first and second sidewalls 124, 126. A horizontal distance (e.g., in the x-direction) between adjacent patterning features 105 is shown as ‘W’. As will be described in greater detail herein, the patterning features 105 may include one or more breaks 129, or areas of incomplete formation, which will be mitigated as a result of subsequent angled material deposition processes.

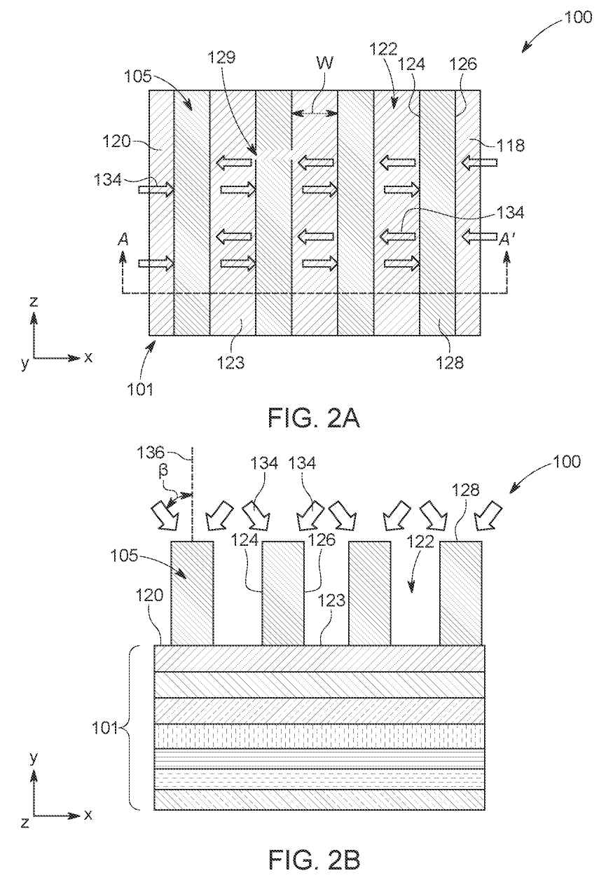

As shown in FIGS. 2A – 2B, a material deposition process may be performed in which a material 134 is directed to the patterning features 105 at non-zero angle ‘β’ relative to a perpendicular 136 extending from the upper surface 128 of the patterning features 105. Although non-limiting, the non-zero angle may be between 10° – 80°. In some embodiments, the material deposition process may include one or more plasma or ion beam processes, and the material 134 may be carbon or silicon-based. For example, the material deposition process may use different carbon-containing chemistries (e.g., methane, acetylene, etc.) and silane-based materials to add layers atop the patterning features 105, while eliminating or at least minimizing deposition within the spaces 122. That is, the material 134 is generally not formed along the first sidewall 124, the second sidewall 126, or the bottom surface 123 between the first and second sidewalls 124, 126. The material 134 may be directed to the upper surface 128 along an entire length (e.g., z-direction) of the patterning features 105.

The material 134 may be delivered as a beam (e.g., ion beam) in a series of successive deposition steps performed in between rotations of the structure 100 and/or a deposition tool or portion thereof. For example, the material 134 may be deposited approximately every 180 degrees, which equates to two rotations for a single beam. In other embodiments, e.g., using a dual beam process in which two beams are directed at the substrate at equal and opposite angles, no rotation may be required. Embodiments herein are not limited in this context.

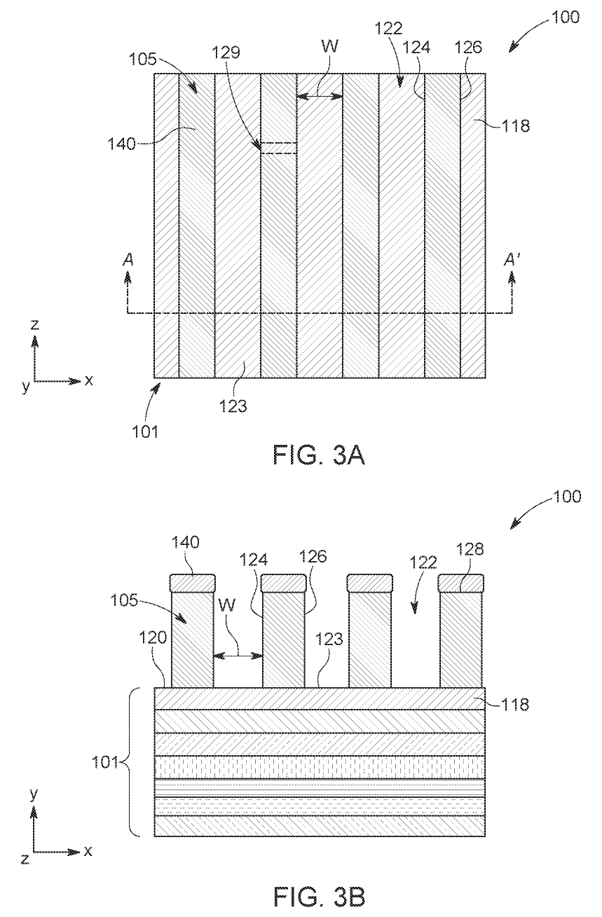

The material deposition process results in a material layer 140 being formed atop the patterning features 105, as shown in FIGS. 3A – 3B. More specifically, the material layer 140 is formed primarily atop the upper surface 128 of the patterning features 105 without significantly being formed along the first or second sidewalls 124, 126, or along the upper surface 120 of the stack of layers 101. In exemplary embodiments, the material layer 140 may be deposited while the spaces 122 are uncovered, i.e., no additional processing has been used to mask the spaces 122 and/or fill the spaces 122 with material before the deposition step. Instead, the material layer 140 is formed only atop the upper surface 128 of the patterning features 105, directly adjacent the spaces 122, thus permitting the CD of the spaces 122 to remain substantially the same following deposition of the material layer 140. Advantageously, the non-zero angle of material delivery prevents the material 134 from being directed into the spaces 122, thus broadening the process window for pattern transferring. More specifically, the non-zero angle of material delivery increases the thickness of the patterning features 105, cures or heals any breaks in the patterning features 105, and increases the robustness of the patterning features 105 during subsequent etching by depositing higher-selectivity material than the existing material of the patterning features 105.

As shown, the material layer 140 may also be formed over/within the break(s) 129 present in one or more of the patterning features 105. Furthermore, should a strip or section of material (sometimes referred to as a “bridge defect”) be present between two adjacent patterning features 105, the material layer 140 will not be deposited thereupon, thus permitting a subsequent etch processes to remove the bridge defect.

In various embodiments, the material of material layer 140 may include a carbon, amorphous silicon, silicon dioxide, silicon nitride, silicon carbide, silicon carbonitride, a boron-carbon film, or other carbon-containing material. Furthermore, the material layer 140 may be the same or different than the material of the patterning features 105. When the patterning features 105 are formed of a photoresist film, deposition of the material layer 140 may be performed at less than 120°C. Other materials systems may enable deposition at higher temperatures, however. In some examples, the structure 100 may be positioned within a process chamber atop a platen or wafer support (not shown), which may be heated to a desired temperature.

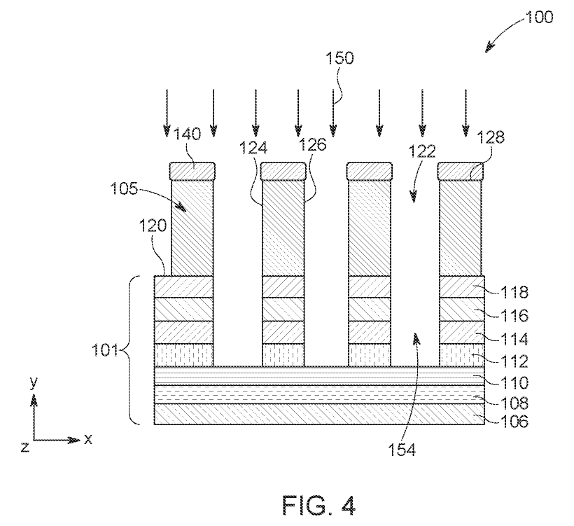

FIG. 4 demonstrates an etch process 150 performed on the structure after the material layer 140 is formed top the plurality of patterning features 105. The etch process 150 may recess the spaces 122 into the stack of layers 101 to form a plurality of trenches 154. In some embodiments, the etch process 150 may include multiple cleaning and/or removal steps, such as an optional descum process to remove residues from surfaces of the trenches 154. Following the etch process 150, up to a 3x improvement of defect window may be achieved.

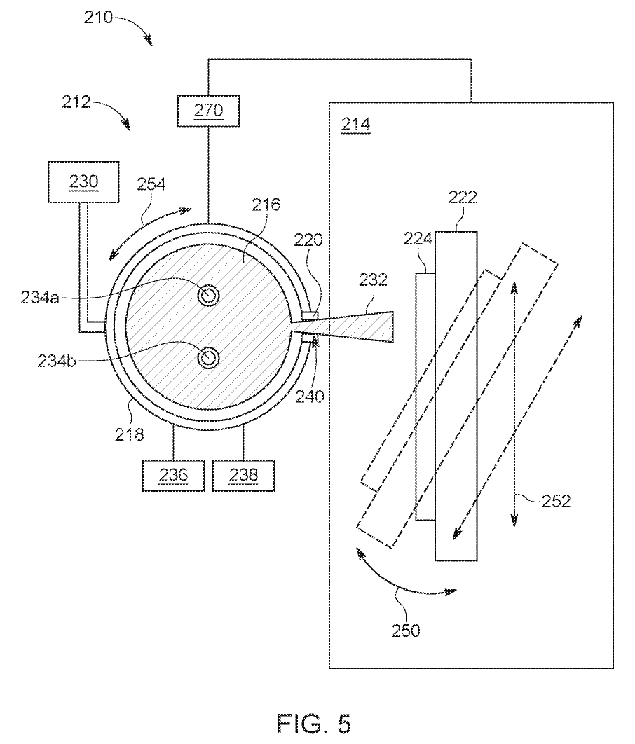

FIG. 5 illustrates a portion of a system 210 useful to perform processes described herein, such as deposition of the material 134 to form the material layer 140. The system 210 may generally include a plasma source 212 disposed adjacent a process chamber 214. The plasma source 212 may be adapted to generate an energetic plasma 216 in a plasma chamber 218, and to emit the plasma 216, e.g., through a nozzle 220 of the plasma chamber 218. In other embodiments, the plasma 216 may be delivered through a second plate (not shown) with a separate aperture situated a specific distance away from the plasma chamber 218. While the plasma chamber 218 is depicted as being generally cylindrical in shape, the present disclosure is not limited in this regard, and the plasma chamber 218 may be implemented in a variety of alterative shapes and configurations.

The process chamber 214 may contain a wafer support or platen 222 adapted to support a substrate 224 (e.g., the structure 100 described herein) in a confronting relationship with the nozzle 220 of the plasma chamber 218. In various embodiments, the platen 222 may be adapted to forcibly retain the substrate 224, such as via electrostatic clamping or mechanical clamping. Additionally, the platen 222 may include a heating element (not shown) for controllably heating the substrate 224 to a desired temperature (e.g., a temperature in a range between room temperature and 450 degrees Celsius) to enhance deposition processes.

The plasma source 212 of the system 210 may be configured to generate the plasma 216 from a gaseous species supplied to the plasma chamber 218 by one or more gas sources 230. The gaseous species may include one or more of SiH4, CH4, NH3, O2, N2, SiCl4, GeH4, Ar, WF6, B2H6, etc. The present disclosure is not limited in this regard. The plasma 216 may be projected through the nozzle 220 in the form of a beam 232 directed at the substrate 224 as further described below. In various embodiments, the plasma source 212 may be a radio frequency (RF) plasma source (e.g., an inductively coupled plasma (ICP) source, a capacitively coupled plasma (CCP) source, a helicon source, an electron cyclotron resonance (ECR) source, etc.). For example, the plasma source 212 may include electrodes 234a, 234b, an RF generator 236, and an RF matching network 238 for igniting and sustaining the plasma 216 in a manner familiar to those of ordinary skill in the art. The present disclosure is not limited in this regard.

The plasma 216 generated in the plasma chamber 218 may contain ionized gas species (ions), electrons, excited neutrals, and free radicals. The plasma chamber 218 of the system 210 is separate from the process chamber 214 where the platen 222 and the substrate 224 reside, and a collimated beam 232 containing free radicals of the plasma 216 is extracted from the plasma chamber 218 and is directed at the substrate 224 in a directionally specific, anisotropic manner.

In a non-limiting example, the radical beam may be extracted through a nozzle 220 or a second aperture plate having an elongated profile. With regard to the pressure differential, the process chamber 214 may be maintained at a first pressure, and the plasma chamber 218 may be maintained at a second pressure higher than the first pressure. In various examples, the first pressure in the process chamber may be in a range of 10⁻⁶ torr to 10⁻² torr, and the second pressure in the plasma chamber 218 may be in a range of 1 millitorr to 1 torr. The present disclosure is not limited in this regard. Thus, the pressure differential between the plasma chamber 218 and the process chamber 214 may provide a motive force for driving free radicals in the plasma 216 from the plasma chamber 218 into the process chamber 214 in the form of beam 232.

The beam 232 may be given its shape and may be collimated using various structures, devices, and techniques. In one example, the beam 232 may be given its shape and may be collimated by the elongated, low-profile nozzle 220 of the plasma chamber 218 or alternatively with a second plate set a specific distance away from 218 with a second aperture slot.

The platen 222 may be rotatable and movable for pivoting and scanning the substrate 224 relative to the plasma chamber 218 as indicated by arrows 250 and 252. Additionally, or alternatively, the plasma chamber 218 may be rotatable about its long axis as indicated by the arrow 254. Thus, the collimated, free radical-containing beam 232 may be projected onto the substrate 224 at various oblique angles in a highly directional, anisotropic manner to deposit films on specific sides and/or portions of surface features (e.g., such as the upper surface 128 of the patterning features 105 in FIGS. 3A – 3B) of the substrate 224 while keeping other sides and/or portions of such surface features free of such depositions (e.g., the first sidewall 124, the second sidewall 126, and the upper surface 120 of the stack of layers 101). In a non-limiting example, the movement and/or rotation of the platen 222 and/or the plasma chamber 218 may facilitate projecting the beam 232 onto the substrate 224 at angles in a range of 10 degrees to 80 degrees relative to a surface of the platen 222 with angular spreads in a range of +/- 5 degrees to +/- 30 degrees.

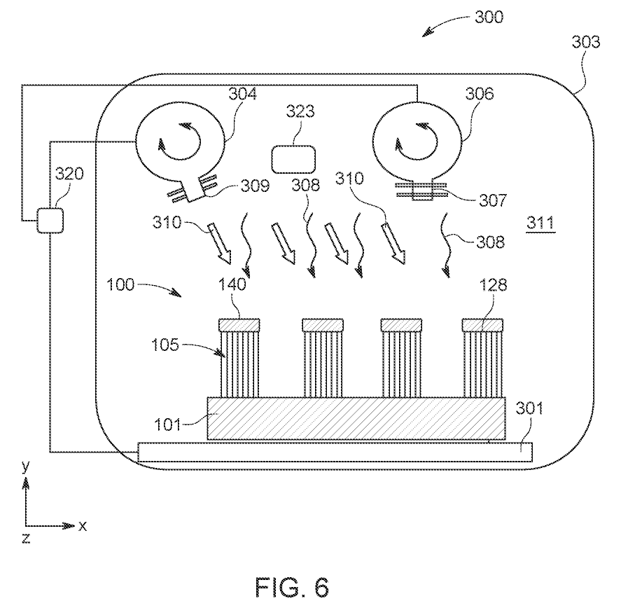

Turning now to FIG. 6, an arrangement or system 300 for selective deposition according to embodiments of the disclosure is shown. Among other things, the system 300 may be used to deposit the material layer 140 over the structure 100, as shown in FIGS. 3A – 3B and described above. The system 300 may include a substrate stage 301 to scan the substrate in the x, y, and/or z-directions. For example, the substrate stage 301 may move the substrate between a first position adjacent a deposition source 306 to a second position adjacent an ion source 304. The system 300 may use a processing apparatus 311, including a process chamber 303 to house the structure 100. In various embodiments, the deposition source 306 may be disposed in a first region of the process chamber 303, while the ion source 304 is disposed in a second region of the process chamber 303.

The processing apparatus 311 may further include a controller 323, coupled to the deposition source 306 and to the ion source 304, wherein the controller 323 may be arranged to control various components of the processing apparatus 311. In brief, the controller 323 may be used to send control signals to a bias source 320 to bias the process chamber 303 with respect to the ion source 304 and/or bias the process chamber 303 with respect to the structure 100, e.g., to change the orientation of the ion source 304 or orientation of the deposition source 306, to scan the substrate stage 301, and so forth.

During processing, species 308 and angled ions 310 may be directed to the structure 100 to form the material layer 140 over the patterning features 105. In some embodiments, the depositing species 308 and angled ions 310 may be directed to the same region of the substrate structure 100, either simultaneously or in sequential fashion. In some embodiments, scanning the substrate stage 301 may take place while the substrate is exposed simultaneously to the depositing species 308 and angled ions 310. In other embodiments where the angled ions 310 and depositing species 308 are directed towards different regions of the process chamber 303, the substrate stage 301 may be scanned so the substrate is exposed sequentially to depositing species 308 from the deposition source 306 and to angled ions 310 from the ion source 304.

The deposition source 306 may provide depositing species 308 in the form of ions, excited neutrals, radicals, or other species capable of depositing on the patterning features 105. In some examples, a feed gas may be fed into the deposition source 306, providing the appropriate species such as SiH₄, CH₄, or NH₃, optionally in combination with other gases, such as oxygen, nitrogen, hydrogen, and so forth, for depositing a given layer, such as silicon, carbon, silicon nitride, silicon oxide, and so forth. In some embodiments, the deposition source 306 may be a first plasma chamber, excited by a microwave or RF power source to generate a plasma including reactive species. The depositing species 308 may be provided as known reactive species to the patterning features 105, where the depositing species 308 are directed through an orifice 307 of the deposition source 306 toward the structure 100, and may generally diffuse toward the structure 100 and impinge upon the patterning features 105 at a desired angle, as described above. In some examples, the depositing species 308 may impinge upon the structure 100 in an isotropic fashion and may tend to form a conformal film coating, as represented by the material layer 140. In some embodiments, the depositing species 308 may deposit in a manner where the deposition is symmetrically arranged on different surfaces of the device, while not being isotropic. For example, where the orifice 307 faces downwardly, the depositing species may deposit on the upper surface 128 of the patterning features 105 more so than on vertical surfaces of the patterning features 105 and more so than on the upper surface of the stack of layers 101 between the patterning features 105.

The material layer 140 may be formed under conditions where the depositing species 308 condense upon the structure 100 with low kinetic energy, such as less than a few eV, and in some cases less than 1 eV energy. In some embodiments, the substrate stage 301 may be biased with respect to the deposition source 306 at zero volts or a slight positive voltage (positive potential), such as +10 V to +50 V. In some embodiments, the deposition source 306 may be rotatable around (about) an axis, such as the z-axis in the Cartesian coordinate system shown.

In some embodiments, the ion source 304 may be a second plasma chamber generating a plasma containing inert gas ions such as Ar⁺, Kr⁺, Xe⁺, or reactive ions, such as O+, N+, O2+. N2+, and so forth. According to various embodiments, the ion source 304 and the deposition source 306 may be arranged with a known triode extraction system, including ground and suppression electrodes. The embodiments are not limited in this context. The ion source 304 may act as an angled ion source where ions are extracted from the ion source 304 through orifice 309 and directed as angled ions 310 to the structure 100. For example, the angled ions 310 may be provided as a collimated ion beam, where the angled ions 310 are parallel to one another or have trajectories forming a low angular spread, such as less than 10 degrees. As such, the angled ions 310 may tend to be shadowed in like regions of similar features within the 3-D structure of the structure 100, such as the patterning features 105. In this manner, the angled ions 310 may impinge upon the upper surface 128 of the patterning features 105 without impinging upon other surfaces of the patterning features or the upper surface of the stack of layers 101. In various embodiments, the angled ions 310 may be provided with ion energy of 50 eV up to 3 keV, or 5 keV, or 10 keV. The embodiments are not limited in this context, however.

According to various embodiments, the angle of incidence of angled ions 310 with respect to a perpendicular to a plane of the substrate may be set by tilting the substrate stage 301 with respect to the ion source 304 and the ions 310, or by tilting the ion source 304 with respect to the substrate stage 301 and the structure 100. In various embodiments, the angle of incidence of angled ions 310 may vary from zero degrees to 85 degrees.

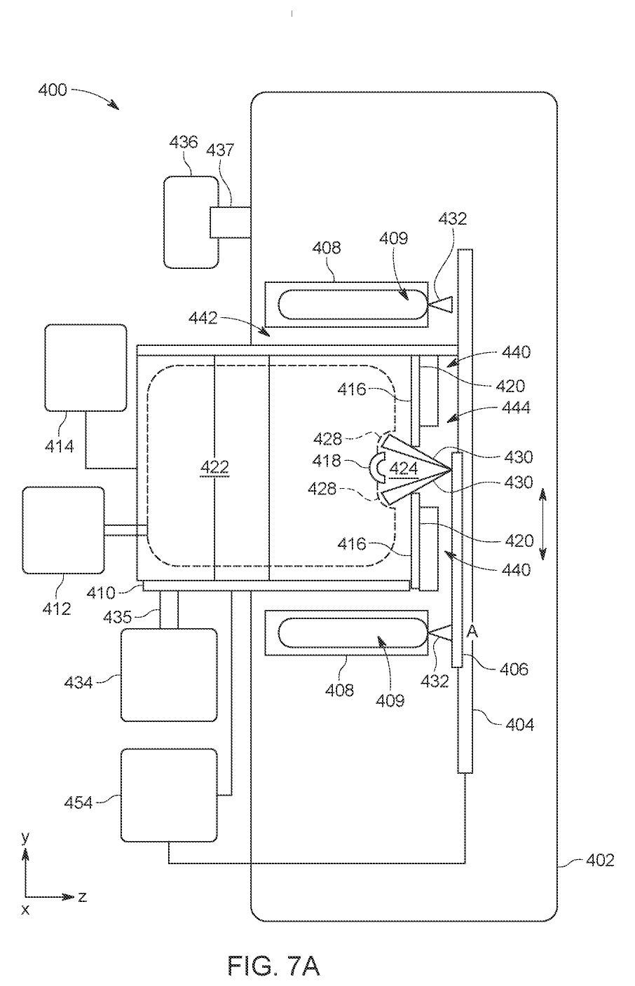

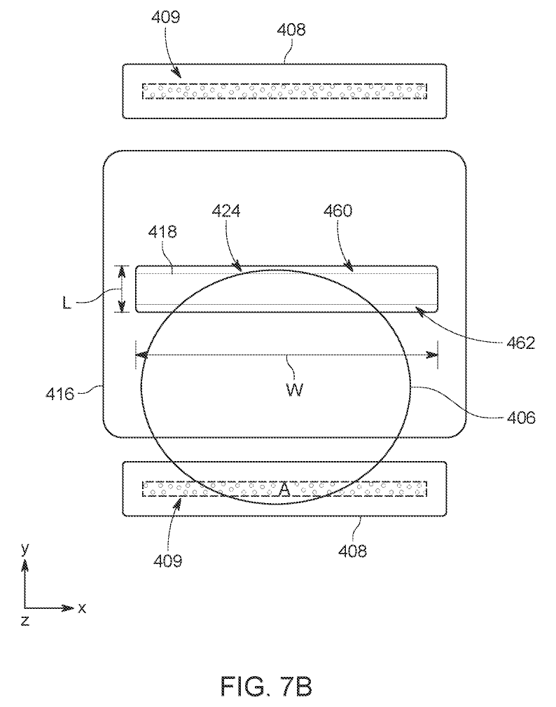

FIGS. 7A – 7B are schematics of a processing apparatus 400 including an exemplary plasma processing chamber suitable for performing a patterning process. Among other things, the apparatus 400 may be used to deposit the material layer 140 over the structure 100, as shown in FIGS. 3A – 3B and described above. The apparatus 400 may include various components that operate together as an apparatus providing novel and improved deposition to a substrate 406. As illustrated, the apparatus 400 may include a process chamber 402 and a substrate stage 404 disposed within the process chamber 402.

The apparatus 400 further includes at least one reactive gas source, shown as the reactive gas source 408. The reactive gas source 408 may have a reactive gas outlet 409 disposed within the process chamber 402. The reactive gas source 408 may be employed to deliver reactive gas 432 to a substrate 406 when the substrate 406 is adjacent the reactive gas source 408. In various embodiments, the reactive gas 432 may be capable of reacting with material of the substrate 406, wherein a first product layer comprising the reactive gas 432 and material from the substrate 406 is formed on an outer surface of the substrate 406. The reactive gas 432 may be delivered as a neutral species, may be delivered as a radical, may be delivered as an ion or may be delivered as a combination of neutrals, radicals and ions in some embodiments.

The apparatus 400 further includes a plasma chamber 410. The plasma chamber 410 may include an extraction plate 416. As illustrated in FIG. 7A, the extraction plate 416 partially separates the plasma chamber 410 from the process chamber 402. The extraction plate 416 also includes an aperture 424 providing gaseous communication between the plasma chamber 410 and the process chamber 402, where the aperture 424 acts as an extraction aperture. In this manner, the plasma chamber 410 may be coupled to the process chamber 402. The aperture 424 may be an elongated aperture that extends along a first direction, such as parallel to the X-axis, as shown in FIG. 7B. For example, the aperture 424 may have a width ‘W’ ranging between 100 mm and 500 mm in some embodiments and a length ‘L’ ranging between 3 mm and 30 mm in some embodiments. The embodiments are not limited in this context. This elongated configuration of aperture 424 allows the extraction of an ion beam ("plasma beam") as a ribbon beam, meaning an ion beam having a cross-section where the beam width is greater than a beam length. Embodiments herein are not limited to a ribbon beam, however.

As further shown in FIG. 7A, the apparatus 400 may include an inert gas source 412 coupled to the plasma chamber 410 to provide inert gas such as Ar, He, Ne, Kr, and so forth. The apparatus 400 may further include additional components such as a power generator 414, where the components together form a plasma source to generate a plasma 422. The plasma 422 may be generated by coupling electric power from the power generator 414 to the rarefied gas provided by inert gas source 412 in the plasma chamber 410 through an adequate plasma exciter (not shown). As used herein, the generic term "plasma source" may include a power generator, plasma exciter, plasma chamber, and the plasma itself. The plasma source may be an inductively coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art. Therefore, depending on the nature of the plasma source, the power generator 414 may be an rf generator, a dc power supply, or a microwave generator, while plasma exciter may include rf antenna, ferrite coupler, plates, heated/cold cathodes, helicon antenna, or microwave launchers.

The apparatus 400 further may include a bias power supply 454 connected to the plasma chamber 410 or to a substrate stage 404, or to the plasma chamber 410 and substrate stage 404. Although not explicitly shown, the plasma chamber 410 may be electrically isolated from the process chamber 402. Extraction of a plasma beam 430 comprising positive ions through the aperture 424 may accomplished by either elevating the plasma chamber 410 at positive potential and grounding the substrate stage 404 directly or via grounding the process chamber 402, or by grounding the plasma chamber 410 and applying negative potential on the substrate stage 404. The bias power supply 454 may operate in either a dc mode or pulsed mode having a variable frequency and duty cycle, or an AC mode. The extraction plate 416 may be arranged generally according to known design to extract ions in the plasma beam 430 in a manner that allows control of the ion angular distribution, i.e., the angle of incidence of the plasma beam 430 with respect to a substrate 406 and the angular spread as detailed below.

In some embodiments, just one plasma beam 430 may be extracted through the aperture 424. In other embodiments, a pair of plasma beams may be extracted through the aperture 424. For example, as illustrated in FIGS. 7A and 7B, a beam blocker 418 may be disposed within the plasma chamber 410 and adjacent the aperture 424, where the beam blocker 418 defines a first extraction aperture 460 and second extraction aperture 462. As shown in FIG. 7A, two plasma beams 430 may be extracted from the plasma chamber 410 and directed to the substrate 406.

As further shown in FIG. 7A, the apparatus 400 may include a pumping port 435 coupled to the plasma chamber 410 and a plasma chamber pump 434 connected to the pumping port 435. The plasma chamber pump 434 may be employed, for example, to reduce concentration of certain species within the plasma chamber 410, as discussed below. The apparatus 400 may further include a process chamber pump 436 coupled to the process chamber 402 via a pumping port 437 to evacuate the process chamber 402.

The apparatus 400 may further include a gas flow restrictor disposed between the reactive gas outlet and the extraction aperture, shown as the gas flow restrictor 420. As shown in FIG. 7A, for example, a gas flow restrictor 420 may be disposed on the outside of extraction plate 416 facing the substrate stage 404. The gas flow restrictor may define a differential pumping channel 440 between at least the plasma chamber 410 and substrate stage 404.

In operation, the substrate stage 404 may scan the substrate parallel to the Y-axis with respect to the extraction plate 416. In this manner, different portions of the substrate 406 may be exposed to the reactive gas 432 at different times. For example, the reactive gas outlet 409 may be elongated as shown in FIG. 7B and may have a width along the X-axis similar to the width W of the aperture 424, and a length along the Y-axis of 3 mm, for example. In various embodiments, the reactive gas outlet 409 may be composed of a multitude of small holes distributed over the X and Y dimensions to define an elongated shape as shown by the dashed lines, for uniform gas distribution along the X dimension. Moreover, the distance between the reactive gas source 408 and substrate 406 along the Z-axis may be 5 mm or less in some examples. The embodiments are not limited in this context. In this manner, the reactive gas 432 may be provided as a narrow, elongated stream that covers the substrate 406 in its entirety along the X-axis, while just covering the substrate 406 over several millimeters in the direction parallel to the Y-axis. Accordingly, the entirety of the substrate 406 may be exposed to the reactive gas 432 in a sequential fashion by scanning the substrate along the Y-axis. Likewise, different portions of the substrate 406 may be exposed to the plasma beam(s) 430 at different times.

Additionally, as illustrated in FIG. 7B, a given region, such as a region ‘A’ of the substrate 406, may be exposed to the reactive gas 432 and plasma beam 430 in a sequential fashion. In this manner, in an example of scanning the substrate 406 from bottom to top, a product layer made from the species of the reactive gas 432 and substrate 406 may initially be formed at the region ‘A’. The product layer may be formed in region ‘A’, and may be the material layer 140 formed atop the patterning features 105, as shown in FIGS. 3A – 3B.

In accordance with embodiments of the disclosure, the gas flow restrictor 420 may define a low conductance channel, shown as differential pumping channel 440, between at least the extraction plate 416 and substrate stage 404. As discussed below, the differential pumping channel 440 may establish a large pressure difference between one end of the differential pumping channel 440 and the other end. The reactive gas source 408 is separated from the plasma chamber 410 by a large conductance aperture in direct communication to a pumping source. The pumping source can be the process chamber pump 436 or any other pumping source made to communicate with aperture 442. In accordance with various embodiments, using appropriate design of aperture 442 and differential pumping channel 440 the partial pressure of the reactive gas in these two spatial regions may differ by 2 to 3 orders of magnitude. Using this differential pumping method, the apparatus 400 may, for example, maintain a partial pressure of the reactive gas 432 adjacent the reactive gas outlet 409 of 1E-3 Torr, while having a partial pressure of 1E-6 Torr at the region 444 adjacent the aperture 424, leading to the plasma chamber 410.

A result of this pressure differential is that species of reactive gas 432 may be prevented from back-streaming into the region 444 or into plasma chamber 410, and may be preferentially pumped through the pumping port 437. This may facilitate the ability to control the composition of plasma beam 430, such as reducing or eliminating reactive gas species from the plasma beam 430. In this manner, a more controllable etch process may be realized by maintaining the exposure of substrate 406 to reactive gas 432 separate from the exposure to the plasma beam 430. Additionally, or alternatively, the plasma chamber 410 may be evacuated by the plasma chamber pump 434, further reducing the concentration of species from reactive gas 432 in plasma chamber 410.

In accordance with various embodiments, the substrate stage 404 may be scanned sequentially under the reactive gas source 408 and plasma chamber 410 while the reactive gas source 408 and plasma chamber 410 are maintained in an ON state. In this manner, the apparatus 400 may provide a material deposition process. Moreover, in some embodiments, the substrate stage 404 may scan a substrate 406 back and forth (up and down in FIG. 7A) in a continuous fashion for a predetermined number of scan cycles in order to deposit a predetermined amount of material on the substrate 406. Since the thickness of a given product layer may be readily calculated, the total thickness to be deposited may readily be controlled according to the number of scan cycles to be performed.

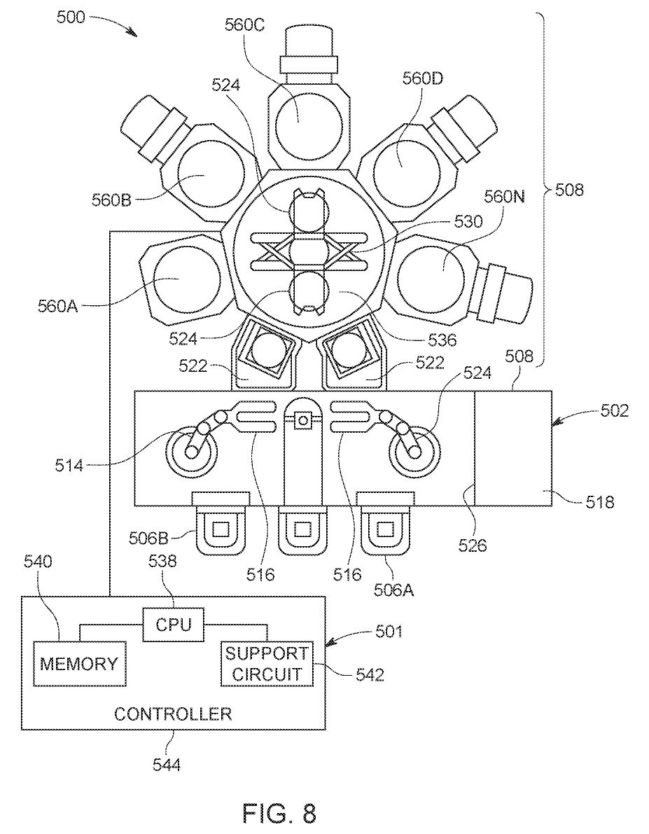

FIG. 8 is a schematic top plan view of an exemplary cluster processing system 500 that includes one or more of the processing chambers operable to form the devices and layers thereof described herein. In one embodiment, the cluster processing system 500 may be an integrated processing system commercially available from Applied Materials, Inc., located in Santa Clara, CA. It is contemplated that other processing systems (including those from other manufacturers) may be adapted to benefit from the disclosure.

The cluster processing system 500 may include a vacuum-tight processing platform 504, a factory interface 502, and a system controller 544. The platform 504 includes a plurality of processing chambers 560A – 560N and at least one load-lock chamber 522 that is coupled to a vacuum substrate transfer chamber 536. In one embodiment, the factory interface 502 comprises at least one docking station 508 and at least one factory interface robot 514 to facilitate transfer of substrates. The docking station 508 is configured to accept one or more front opening unified pod (FOUP). The factory interface robot 514 having a blade 516 disposed on one end of the robot 514 is configured to transfer the substrate from the factory interface 502 to the processing platform 504 for processing through the load lock chambers 522. Optionally, one or more metrology stations 518 may be connected to a terminal 526 of the factory interface 502 to facilitate measurement of the substrate from the FOUPS 506A-B.

Each of the load lock chambers 522 have a first port coupled to the factory interface 502 and a second port coupled to the transfer chamber 536. The load lock chambers 522 are coupled to a pressure control system (not shown) which pumps down and vents the load lock chambers 522 to facilitate passing the substrate between the vacuum environment of the transfer chamber 536 and the substantially ambient (e.g., atmospheric) environment of the factory interface 502.

In one embodiment of the cluster processing system 500, the cluster processing system 500 may include one or more processing chambers 560A – 560N, which may include a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, curing chamber, lithographic exposure chamber, or other similar type of semiconductor processing chambers. More specifically, etch chamber 560A may include an etch tool operable to perform an etch process, such etch process 150 shown in FIG. 4 and described herein. Meanwhile, deposition chamber 560B may include a deposition tool operable to perform an angled material/film deposition using a beam delivered at a non-zero angle to deposit a material atop a plurality of patterning features, e.g., as shown in FIGS. 3A – 3B. In various embodiments, the deposition tool may be any of the following described herein: system 210, system 300, and/or apparatus 400.

In yet other embodiments, the deposition tool may be a gas cluster ion beam (GCIB) or gas cluster beam (GCB) deposition tool, which is a vacuum system operable to form a thin film of material, such as the material 134 formed along the upper surface 128 of the patterning features 105 shown in FIGS. 3A – 3B. GCIB realizes ultra-low energy ion irradiation and high energy density deposition at the surface of the patterning features 105. Carbon and silicon-based films may be deposited with GCIB-assisted depositions. In one approach, the process may include providing a substrate in a reduced pressure environment, generating the at least one GCIB from a pressurized gas mixture, and selecting ion cluster acceleration potential and ion cluster dose to achieve a desired thickness of the film. The GCIB may form the material layer 140 as a thin film on just the upper surface of the patterning features 105.

In various embodiments, the etch and deposition processes can be performed in the same chamber, such as an angled plasma beam chamber, e.g., by changing the chemistry being used in the chamber. The etch and deposition processes may occur sequentially, but they may also occur simultaneously, by running both the etch and the deposition chemistries at the same time.

The transfer chamber 536 has a vacuum robot 530 disposed therein. The vacuum robot 530 has one or more blades capable of transferring substrates 524 among the load lock chambers 522, the metrology system 510 and the processing chambers 560A – 560N.

The system controller 544 is coupled to the cluster processing system 500. The system controller 544, which may include the computing device 501 or be included within the computing device 501, controls the operation of the cluster processing system 500 using a direct control of the processing chambers 560A – 560N of the cluster processing system 500. Alternatively, the system controller 544 may control the computers (or controllers) associated with the processing chambers 560A – 560N and the cluster processing system 500. In operation, the system controller 544 also enables data collection and feedback from the respective chambers to optimize performance of the cluster processing system 500.

The system controller 544, much like the computing device 501 described above, generally includes a central processing unit (CPU) 538, a memory 560, and support circuits 532. The CPU 538 may be one of any form of a general-purpose computer processor that can be used in an industrial setting. The support circuits 532 are conventionally coupled to the CPU 538 and may comprise cache, clock circuits, input/output subsystems, power supplies, and the like. The software routines transform the CPU 538 into a specific purpose computer (controller) 534. The software routines may also be stored and/or executed by a second controller (not shown) that is located remotely from the cluster processing system 500.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

For the sake of convenience and clarity, terms such as "top," "bottom," "upper," "lower," "vertical," "horizontal," "lateral," and "longitudinal" will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word "a" or "an" is to be understood as including plural elements or operations, until such exclusion is explicitly recited. Furthermore, references to "one embodiment" of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, "depositing" and/or “deposited” may include any now known or later developed techniques appropriate for the material to be deposited (such as material 134 of FIGS. 2A, 2B) including yet not limited to, for example: chemical vapor deposition (CVD), low-pressure CVD (LPCVD), and plasma-enhanced CVD (PECVD). Additional techniques may include semi-atmosphere CVD (SACVD) and high-density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a plurality of patterning features over a stack of layers of a semiconductor structure; and
forming a material layer atop the plurality of patterning features by directing a material at a non-zero angle relative to a normal extending perpendicular from a plane defined by an upper surface of the plurality of patterning features, wherein the material layer is formed along the upper surface of the plurality of patterning features without being formed along a sidewall of the plurality of patterning features.

2. The method of claim 1, wherein the material layer is formed along the upper surface of the plurality of patterning features without being substantially formed along an upper surface of the semiconductor structure.

3. The method of claim 1, wherein the plurality of patterning features define a plurality of spaces, and wherein the material is directed to the upper surface of the plurality of patterning features while the plurality of spaces are uncovered.

4. The method of claim 3, further comprising performing an etch process after the material layer is formed atop the plurality of patterning features to recess the plurality of spaces into the stack of layers.

5. The method of claim 1, further comprising directing the material in a series of successive deposition steps, wherein the semiconductor structure is rotated between the series of successive deposition steps.

6. The method of claim 1, wherein the plurality of patterning features comprises a photoresist or a hardmask.

7. The method of claim 6, wherein the photoresist is a metal oxide resist or a chemically amplified resist.

8. The method of claim 1, wherein directing the material at the non-zero angle comprises depositing a carbon-based film or a silicon-based film along the upper surface of the plurality of patterning features.

9. The method of claim 1, further comprising:
generating ions and a reactive species in a plasma chamber; and
directing the ions and the reactive species to the patterning features to form the material layer.

10. A method of forming a material layer atop a plurality of patterning lines, the method comprising:
providing the plurality of patterning lines and a plurality of spaces over a stack of layers of a semiconductor structure; and
forming the material layer atop the plurality of patterning lines by directing a material at a non-zero angle relative to a normal extending perpendicular from a plane defined by an upper surface of the plurality of pattering lines, wherein the material layer is formed along the upper surface of the plurality of patterning lines without being formed along a sidewall of the plurality of patterning lines.

11. The method of claim 10, wherein the material layer is formed along the upper surface of the plurality of patterning lines without substantially being formed along an upper surface of the semiconductor structure.

12. The method of claim 10, wherein the material is formed using a gas cluster beam deposition process.

13. The method of claim 12, further comprising performing an etch process after the material layer is formed atop the plurality of patterning lines to recess the plurality of spaces into the stack of layers.

14. The method of claim 10, further comprising directing the material in a series of successive deposition steps, wherein the semiconductor structure is rotated between the series of successive deposition steps.

15. The method of claim 10, wherein the plurality of patterning lines comprises a photoresist or a hardmask, and wherein directing the material at the non-zero angle comprises depositing a carbon-based film or a silicon-based film along the upper surface of the plurality of patterning lines.

16. A pattern transfer process, comprising:
providing a plurality of patterning lines and a plurality of spaces over a stack of layers of a semiconductor structure; and
forming a material layer atop the plurality of patterning lines by directing a material at a non-zero angle relative to a normal extending perpendicular from a plane defined by an upper surface of the plurality of pattering lines, wherein the material layer is formed along the upper surface of the plurality of patterning lines without being formed along a sidewall of the plurality of patterning lines, and wherein the material is directed using a directional chemical vapor deposition or a directional plasma vapor deposition.

17. The pattern transfer process of claim 16, wherein the material layer is formed along the upper surface of the plurality of patterning lines without being substantially formed within the plurality of spaces.

18. The pattern transfer process of claim 16, wherein the material is directed to the upper surface of the plurality of patterning lines while the plurality of spaces are uncovered.

19. The pattern transfer process of claim 16, further comprising performing an etch process after the material layer is formed atop the plurality of patterning lines to recess the plurality of spaces into the stack of layers.

20. The pattern transfer process of claim 16, further comprising directing the material in a series of successive deposition steps, wherein the semiconductor structure is rotated between the series of successive deposition steps, and wherein the deposition process comprises at least one of the following: a directional chemical vapor deposition, a directional plasma vapor deposition.
